(19) United States
(12) Patent Application Publication
(10) Pub. No.: US 2026/0223487 A1
(43) Pub. Date: Jul. 30, 2026

(54) PROCESS FOR MANUFACTURING AN ELECTRONIC DEVICE

(71) Applicant: Aledia, Champagnier (FR)

(72) Inventor: Pascal Guenard, Froges (FR)

(73) Assignee: Aledia, Champagnier (FR)

(21) Appl. No.: 19/142,604

(22) PCT Filed: Dec. 7, 2023
(86) PCT No.: PCT/EP2023/084722

§ 371 Date: Jun. 23, 2025

(30) Foreign Application Priority Data
Dec. 28, 2022 (FR) FR2214577

(51) Int. Cl. H10H 20/01

(52) U.S. Cl. CPC H10H 20/019; H10H 20/017

(57) ABSTRACT

A method for manufacturing an electronic device, including manufacturing a plate including several copies of the electronic device, forming weakened areas in a support by means of a laser, attaching the plate to the support after the weakened areas have been formed, etching the plate in the extension of the weakened areas, and breaking the support at the weakened areas to separate the electronic devices.

This patent application claims the priority of French patent application FR22/14577, which will be considered an integral part of this description.

### TECHNICAL FIELD

The present description relates generally to methods for manufacturing electronic devices, in particular optoelectronic devices comprising light-emitting diodes.

### BACKGROUND ART

One example of a method for manufacturing an electronic device comprises forming, on a support, a plate comprising several copies of the electronic device, and then separating the electronic devices. Separating the electronic devices can be achieved by cutting the plate and the support, in particular by sawing. A disadvantage of such a method for separating is that the cutting lines are wider than 100 μm. For some applications, it is desirable for the cutting lines to have a reduced width, in particular to reduce material losses.

A method for separating electronic devices to obtain cutting lines of reduced width comprises local weakness of the support by laser processing enabling the support to be broken by mechanical action to separate the electronic devices. One drawback is that laser processing can damage electronic device components close to the cutting lines. This disadvantage can be particularly pronounced when the electronic devices each comprise a plurality of three-dimensional semiconductor elements of nanometric or micrometric size, separated by an electrically insulating material. Indeed, since the size of the three-dimensional semiconductor elements and the distance separating them are reduced, the thermal dissipation of the heat brought about by laser processing can result in damage to the three-dimensional semiconductor elements close to the cutting lines.

### SUMMARY OF INVENTION

One embodiment address all or some of the drawbacks of known methods for manufacturing electronic devices.

According to one object of one embodiment, the width of the cut lines in the plate comprising several copies of the electronic device, is less than 100 μm.

According to one object of one embodiment, components of electronic devices close to the cutting lines are not damaged.

One embodiment provides a method for manufacturing an electronic device, comprising manufacturing a plate comprising a plurality of copies of the electronic device, the plate being attached to a substrate, forming weakened areas in a support by means of a laser, attaching the plate to the support after the weakened areas have been formed, removing the substrate after the plate has been attached to the support, etching the plate in the extension of the weakened areas after the substrate has been removed, and breaking the support at the weakened areas to separate the electronic devices. As the step of laser processing of the support to form the weakened areas in the support is carried out before the step of attaching the support to the plate comprising the electronic devices, this advantageously prevents the laser processing from damaging electronic components of the electronic devices on the plate.

According to one embodiment, attaching the plate to the support is performed by bonding. This may take the form of a bonding using a layer of adhesive, which can advantageously be implemented simply and at reduced cost. Molecular bonding can also be used, which allows the need for an adhesive layer between the support and the plate to be avoided.

According to one embodiment, the method comprises a step of thinning the support after attaching the plate to the support, and before breaking the support at the weakened areas. This makes advantageously it easier to break the support at the weakened areas.

According to one embodiment, etching the plate in the extension of the weakened areas is performed by dry etching or wet etching. This allows trenches of reduced thickness to be formed in the plate.

According to one embodiment, the support is laser-transparent at least in the weakened areas. This advantageously allows localized weakened areas to be created.

According to one embodiment, the step of attaching the plate to the support after forming the weakened areas comprises a step of positioning first marks of the support with respect to second marks of the plate, so that each electronic device to be separated is positioned between two weakened areas among the weakened areas.

According to one embodiment, the support is at least partly made of glass, quartz, or sapphire. This advantageously allows using support that are commonly used in laser processings.

According to one embodiment, the electronic device comprises light-emitting diodes. Advantageously, forming weakened areas does not lead to damage to light-emitting diodes adjacent to the desired cutting lines. According to one embodiment, each light-emitting diode comprises a three-dimensional semiconductor element of nanometric or micrometric size, corresponding to a microwire, nanowire, or pyramid-shaped structure of nanometric or micrometric size, and an active layer covering the three-dimensional semiconductor element.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, FIG. 1D, FIG. 1E, FIG. 1F, and FIG. 1G are each a schematic partial cross-sectional view of the structure obtained in one step of a method for manufacturing an electronic device;

FIG. 2 is a partial schematic cross-sectional view of one embodiment of a support;

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N are each schematic partial cross-sectional views of the structure obtained in one step of one embodiment of a method for manufacturing an optoelectronic device comprising light-emitting diodes; and

FIG. 4, FIG. 5, and FIG. 6 each show a schematic partial cross-sectional view of one embodiment of a light-emitting diode.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

In the following description, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures, or to a probe as orientated during normal use.

Unless specified otherwise, the expressions “around”, “approximately”, “substantially” and “in the order of” signify within 10%, and preferably within 5%. In the case of angle, the expressions “around”, “approximately”, “substantially” and “in the order of” signify within 10%, and preferably within 5%. Further, one herein considers that the terms “insulating” and “conductive” respectively signify “electrically insulating” and “electrically conductive”.

By optoelectronic devices, one means devices adapted to convert an electrical signal into electromagnetic radiation or vice versa, and in particular devices dedicated to the detection, measurement or emission of electromagnetic radiation.

The transmittance of a layer corresponds to the ratio of the intensity of radiation leaving the layer through an exit face to the intensity of radiation entering the layer through an entrance face opposite the exit face. In the rest of the description, a layer or film is said to be opaque to radiation when the transmittance of the radiation through the layer or film is less than 10%. For the rest of the description, a layer or film is said to be transparent to radiation when the transmittance of the radiation through the layer or film is higher than 10%.

According to the present invention, the step of laser processing of the support to form weakened areas in the support is carried out before the step of attaching to the support of the plate comprising several copies of the electronic device. Advantageously, this advantageously allows avoiding the laser processing from damaging the electronic components of the electronic devices on the plate.

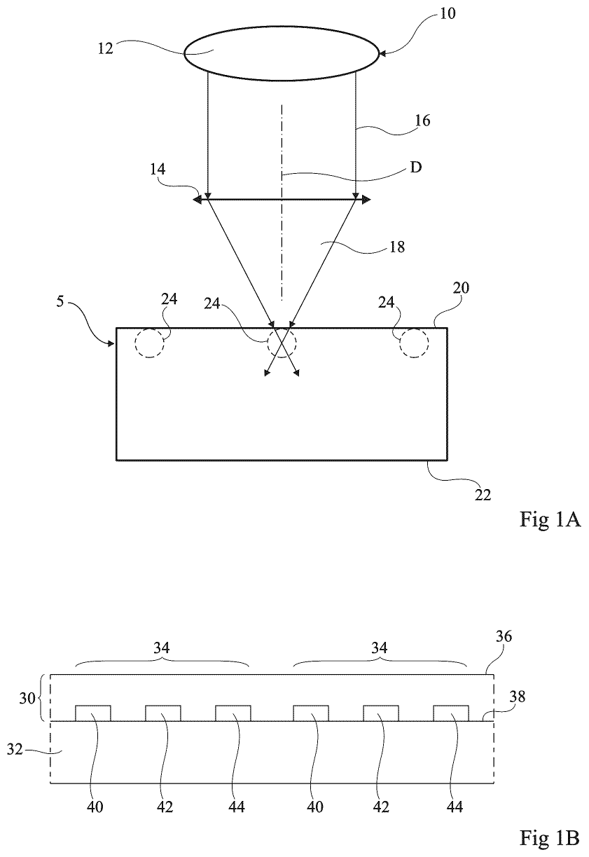

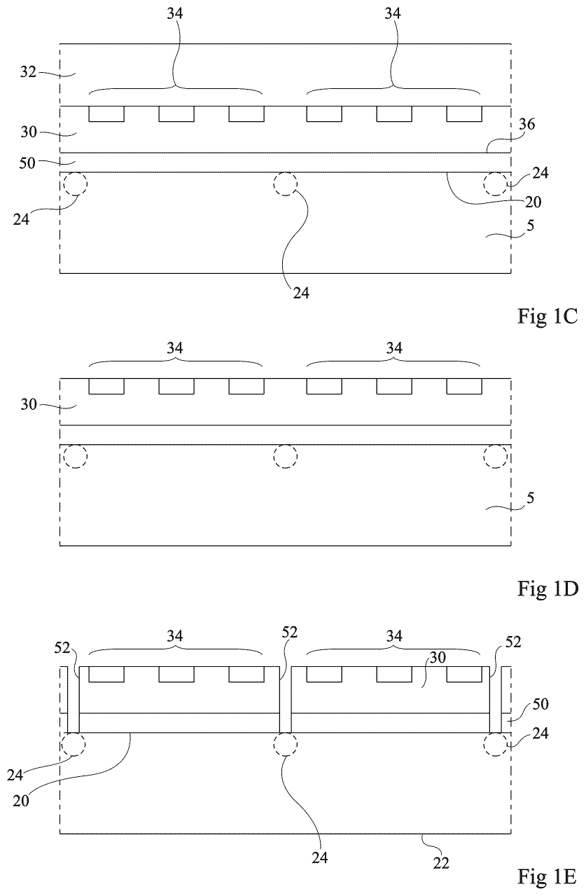

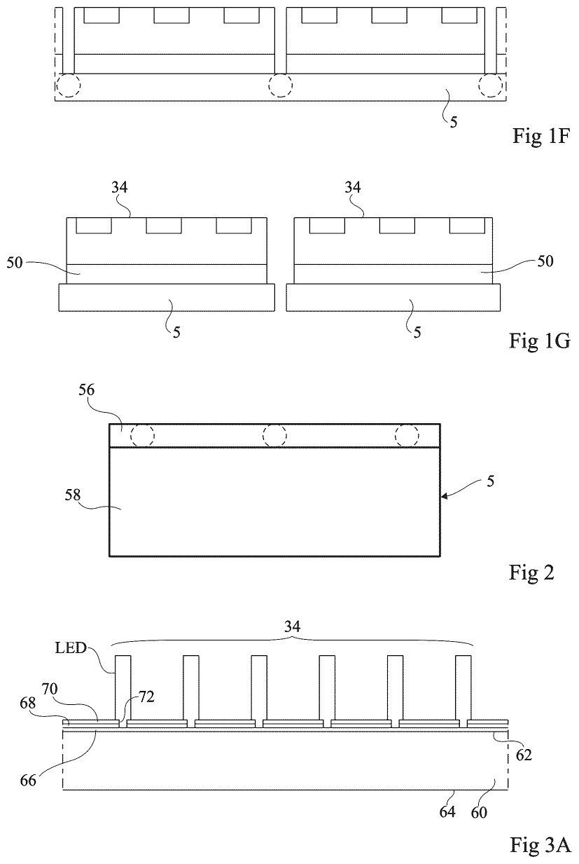

FIG. 1A, FIG. 1B, FIG. 1C, FIG. 1D, FIG. 1E, FIG. 1F, and FIG. 1G are each a schematic, partial cross-sectional view of the structure obtained in one step of an embodiment of a method for manufacturing an electronic device.

FIG. 1A is a partial schematic cross-sectional view illustrating a step of locally weakening a support 5 using a laser processing system 10.

The processing system 10 comprises a laser source 12 and a focusing optical device 14 having an optical axis D. The source 12 is adapted to supply an incident laser beam 16 to the focusing optical device 14, which supplies a converging laser beam 18. The focusing optical device 14 may comprise one optical component, two optical components, or more than two optical components, one optical component corresponding, for example, to a lens. Preferably, the incident laser beam 16 is substantially collimated along the optical axis D of the focusing optical device 14.

The support 5 comprises two opposite faces 20, 22, with the laser beam 18 entering the support 5 through the face 20. According to one embodiment, the faces 20 and 22 are parallel to each other. According to one embodiment, the faces 20 and 22 are flat. According to one embodiment, the thickness of the support 5 is between 50 μm and 3 mm. According to one embodiment, the support 5 has a single-layer structure and is made of a single first material, such as glass, quartz, silicon, or sapphire. The support 5 is then laser-transparent. In another embodiment, the support 5 has a multilayer structure, with a top layer made of the first material. At least the top layer is then laser-transparent.

Laser processing consists in weakening zones 24 of the support 5, using a laser stealth dicing method, in particular a low-energy laser. By way of example, three weakened areas 24 are shown as dotted lines in FIG. 1A. According to one embodiment, the weakened areas 24 extend into the support 5 from the face 20 of the support 5, over a thickness of between 5 μm and 100 μm. According to one embodiment, each weakened area 24 is between 0.5 μm and 5 μm wide. Each weakened area 24 corresponds to a local melting of the support 5 without material shrinkage.

According to one embodiment, the wavelength of the laser beam 18 supplied by the processing system 10 is between 100 nm and 3,000 nm, depending on the material to be weakened. According to one embodiment, the laser beam 18 is emitted by the processing system 10 in the form of one pulse, two pulses or more than two pulses, each pulse having a duration of between 0.1 ps and 1,000 ps. The laser beam energy for each pulse is between 1 μJ and 100 μJ.

FIG. 1B is a schematic partial cross-sectional view of the structure obtained after manufacturing a plate 30 on a substrate 32, the plate 30 comprising several copies of an electronic device 34, two copies of the electronic device 34 being shown by way of example in FIG. 1B. Plate 30 comprises a upper face 36 and a lower face 38, opposite the upper face 36. The lower face 38 is in contact with the substrate 32. The upper face 36 is preferably flat. According to one embodiment, the thickness of plate 30 is between 1 μm and 100 μm. The electronic device 34 comprises electronic components 40, 42, 44, three electronic components 40, 42, 44 being shown by way of example for each electronic device 34 in FIG. 1B. According to one embodiment, the electronic device 34 is an optoelectronic device. The electronic components 40, 42, 44 may then comprise light sources, in particular light-emitting diodes.

FIG. 1C is a schematic partial cross-sectional view of the structure obtained after a step of attaching the structure shown in FIG. 1B to the face 20 of the support 5 shown in FIG. 1A. The plate 30 is attached to the support 5 on the face 36 side. According to one embodiment, attaching the plate 30 to the support 5 is performed by adhesive bonding via a layer of adhesive 50. In another embodiment, not shown, attaching the plate 30 to the support 5 is performed by molecular bonding. In this case, the face 36 of the plate 30 is in direct physical contact with the face 20 of the support 5.

The weakened areas 24 are located in the extension of the desired separation lines between the electronic devices 34. The separation lines correspond to the parts of the plate 30 to be removed in order to separate the electronic devices 34. The desired separation lines between the electronic devices and the weakened areas 24 are superimposed, the desired separation lines overlapping the weakened areas 24. Correct positioning of the plate 30 relative to the support 5 is achieved using, for example, marks on the plate 30 and marks on the support 5 (marks not shown).

FIG. 1D is a partial schematic cross-sectional view of the structure obtained after a step of removing the substrate 32, for example by dry etching, in particular by plasma etching, or by wet etching, or by chemical-mechanical polishing (CMP). Additional steps can then be provided to continue manufacturing the electronic devices 34 on the plate 30, particularly forming conductive pads.

FIG. 1E is a schematic partial cross-sectional view of the structure obtained after a step of etching trenches 52 in the plate 30 at the desired separation lines of the electronic devices 34. Etching is for example carried out by dry etching, in particular plasma etching. The trenches 52 may extend into the adhesive layer 50 until they reach the face 20 of the support 5 at the weakened areas 24. According to one embodiment, the trenches 52 do not extend into the support 5. The trenches 52 can be obtained by chemical etching. According to one embodiment, the width of each trench 52 is between 1 μm and 20 μm.

FIG. 1F is a schematic partial cross-sectional view of the structure obtained after a step of thinning the support 5 from face 22. Depending on the nature of the material or materials constituting the support 5, the thinning step may be carried out by grinding and/or by CMP. The CMP step may comprise, simultaneously or successively, mechanical polishing steps and chemical etching steps. At the end of the thinning step, the thickness of the support 5 is between 50 μm and 200 μm. According to one embodiment, the thickness of the plate 10 is less, in particular by at least a factor of 2, than the thickness of support 5 after thinning.

FIG. 1G is a schematic partial cross-section of the structure obtained after a step of mechanically breaking the support 5 at the weakened areas 24. Separate electronic devices 34 are thus obtained. According to a non-illustrated embodiment, the breaking step comprises attaching a mechanically stretchable adhesive film to the support 5, on the side of the support 5 opposite the electronic devices 34, extending the adhesive film in the plane of the adhesive film, the electronic devices 34 then being separated but still attached to the adhesive film, and detaching the electronic devices from the adhesive film.

The method may include subsequent steps, particularly a step of removing portions of support 5 and the adhesive layer 50 from beneath each electronic device 34. In the case where the support 5 is kept for future use of the electronic device 34, the support 5 can advantageously be transparent to the light radiation emitted by the electronic device 34.

Advantageously, the embodiment of the manufacturing method allows that laser processing of the support 5 to form the weakened areas 24 does not damage the electronic components 40, 42, 44 of the plate 30, since laser processing of the support 5 is carried out before attaching the plate 30 to the support 5.

FIG. 2 shows a cross-sectional view of an embodiment of support 5. According to one embodiment, the support 5 has a multi-layer structure and comprises a layer 56 of the first material covering a substrate 58 of a second material different from the first material. Weakened areas 24 are formed in the layer 56. The substrate 58 can be laser-transparent. According to one embodiment, the second material is a semiconductor material. The semiconductor material may be silicon, germanium, or a mixture of at least two of these compounds. Preferably, the substrate 58 is made of silicon, more preferably monocrystalline silicon. Alternatively, substrate 58 can be at least partly made of a non-semiconductor material, such as an electrically insulating or electrically conductive material. The thickness of the layer 56 is between 50 μm and 200 μm. Advantageously, the second material making up the substrate 58 is selected to facilitate the thinning step described above in relation to FIG. 1F. In particular, determining the end of the thinning step is facilitated since it corresponds to the complete removal of the substrate 58.

A more detailed embodiment will now be described in the case where the electronic device 34 is an optoelectronic device and the electronic components 40, 42, 44 comprise light-emitting diodes comprising three-dimensional semiconductor elements of nanometric or micrometric size, in particular microwires or nanowires or pyramid-shaped structures covered with active layers. Indeed, for such optoelectronic devices 34, performing separation of the electronic devices 34 using the formation of weakened areas in a support by laser processing while the plate containing the electronic devices 34 is attached to the support causes significant deterioration of the light-emitting diodes adjacent to the desired cutting lines.

The term “microfil” or “nanowire” designates a three-dimensional structure elongated in a preferred direction, at least two dimensions of which, called minor dimensions, are comprised between 5 nm and 5 μm, preferably between 100 nm and 2 μm, more preferably between 200 nm and 1.5 μm, the third dimension, called major dimension or height, being higher than or equal to 1 times, preferably higher than or equal to 3 times and even more preferably higher than or equal to 5 times, the largest of the minor dimensions. In some embodiments, the height of each microwire or nanowire may be higher than or equal to 500 nm, preferably between 1 μm and 50 μm. In the rest of the description, the term “wire” is used to mean “microwire or nanowire”.

The cross-section of wires can have different shapes, for example, oval, circular or polygonal, in particular triangular, rectangular, square or hexagonal. It will be understood that the term “average diameter” used in connection with a cross-section of a wire designates a quantity associated with the surface area of the wire in this cross-section, corresponding, for example, to the diameter of the disk having the same surface area as the cross-section of the wire.

In the rest of the description, the term pyramid refers to a three-dimensional structure, part of which is pyramidal or elongated conical in shape. This pyramidal structure can be truncated, i.e. the top of the cone is absent, leaving a plateau. The base of the pyramid is inscribed in a square with side dimensions ranging from 100 nm to 10 μm, preferably between 0.2 μm and 2 μm. The polygon forming the base of the pyramid may be a hexagon. The height of the pyramid between the base of the pyramid and the apex or summit plateau varies from 100 nm to 20 μm, preferably between 200 nm and 2 μm.

In the rest of the description, embodiments will be described in the case of an optoelectronic device with light-emitting diodes comprising microwires or nanowires. However, it is clear that these embodiments may relate to an optoelectronic device with light-emitting diodes comprising micrometer-or nanometer-sized pyramids.

The wires mainly comprise at least one semiconductor material, preferably more than 60% by mass, more preferably more than 80% by mass. The semiconductor material may be silicon, germanium, silicon carbide, a III-V compound, a II-VI compound, or a combination of at least two of these compounds.

Examples of Group III elements comprise gallium (Ga), indium (In), or aluminum (Al). Examples of III-N compounds are GaN, AIN, InN, InGaN, AlGaN, or AlInGaN. Other Group V elements can also be used, for example, phosphorus or arsenic. In general, the elements in compound III-V can be combined in different mole fractions. Examples of Group II elements comprise Group IIA elements, particularly beryllium (Be) and magnesium (Mg), and Group IIB elements, particularly zinc (Zn), cadmium (Cd), and mercury (Hg). Examples of group VI elements include group VIA elements, particularly oxygen (O) and tellurium (Te). Examples of II-VI compounds are ZnO, ZnMgO, CdZnO, CdZnMgO, CdHgTe, CdTe or HgTe. In general, the elements in compound II-VI can be combined in different molar fractions. The semiconductor material of the wires can include a dopant, for example silicon providing N-type doping of a III-N compound, or magnesium providing P-type doping of a III-N compound.

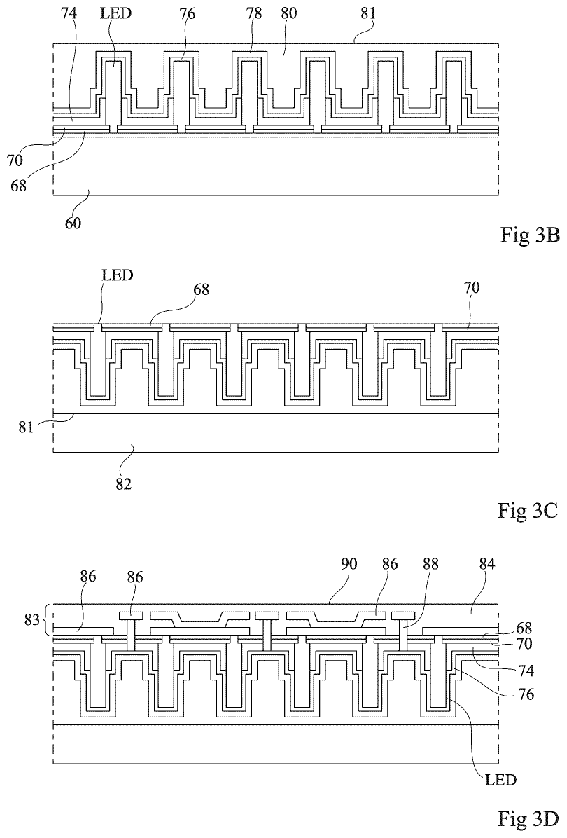

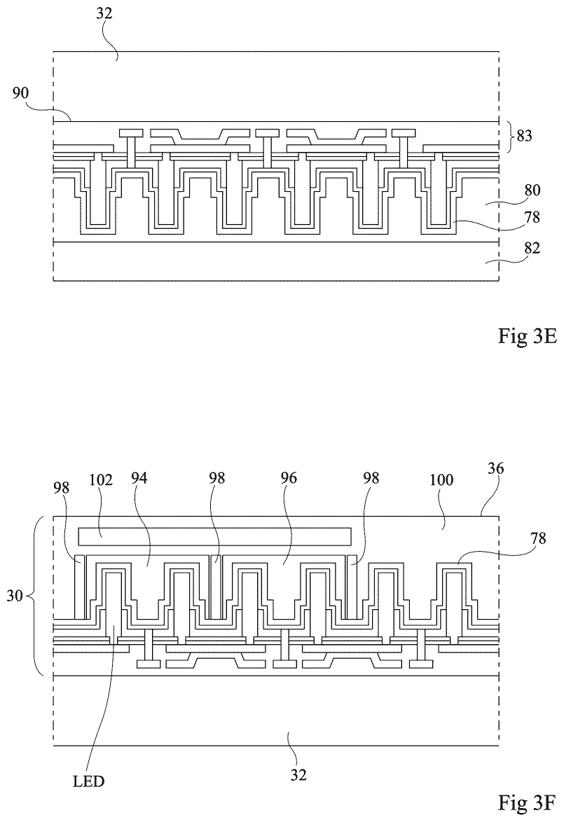

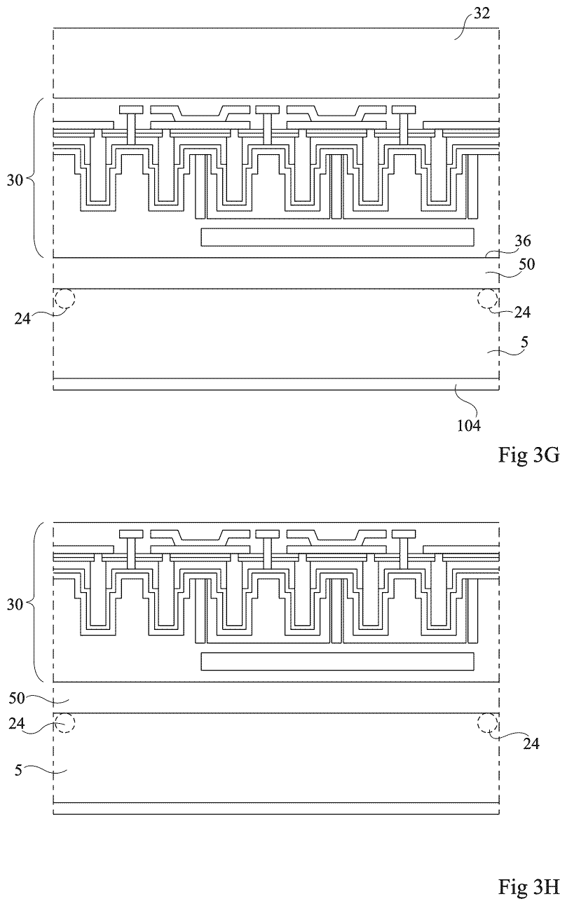

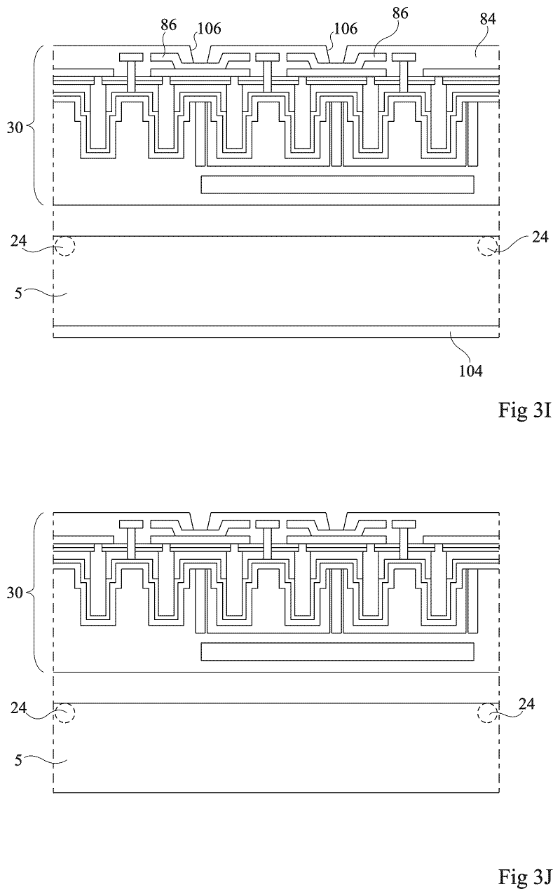

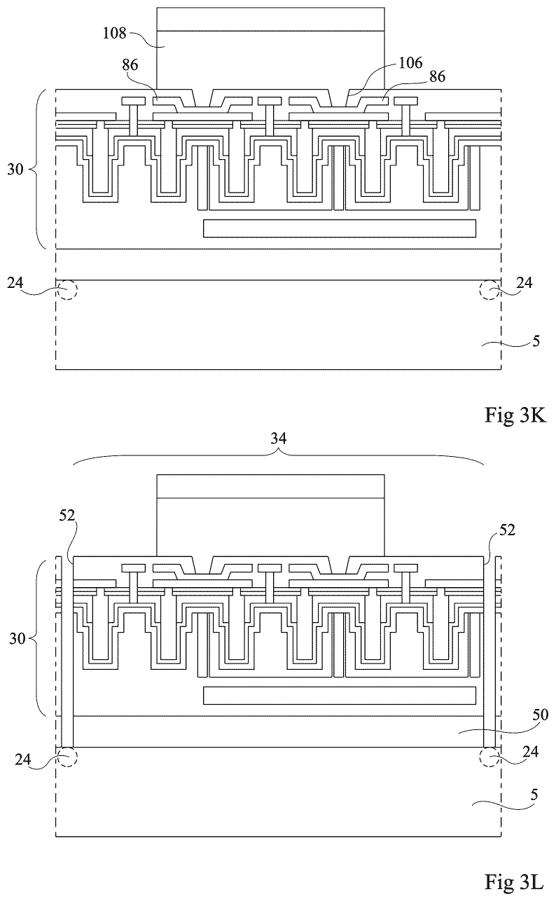

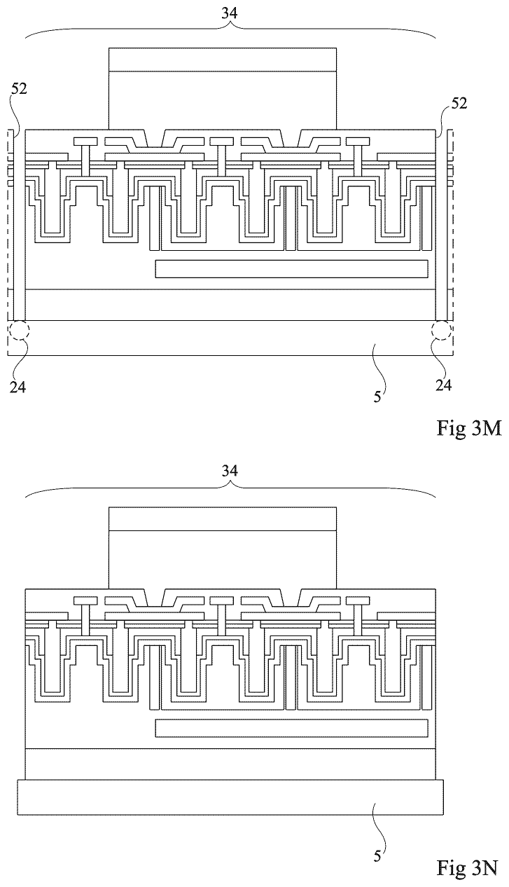

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N are each a schematic, partial cross-sectional view of the structure obtained in one step of an embodiment of a method for manufacturing the optoelectronic device 34.

FIG. 3A, FIG. 3B, FIG. 3C, FIG. 3D, FIG. 3E, and FIG. 3F illustrate the manufacturing of the plate 30 on the substrate 32, in the case where the plate 30 comprises several copies of the nanowire or microwire optoelectronic device 34.

FIG. 3A is a schematic partial cross-sectional view of the structure obtained after the following steps:
forming, on a substrate 60 comprising opposite faces 62 and 64, the face 62 preferably being flat at least at the level of the light-emitting diodes, a germination layer 66 made of a wire-growth-promoting material and arranged on the face 62;
forming a stack of two insulating layers 68 and 70 covering the germination layer 66 and comprising openings 72 exposing portions of the germination layer 66; and
causing the growth, for each opening 72, of a light-emitting diode LED in contact with the germination layer 66 through the opening 72, six light-emitting diodes LED of a single optoelectronic device 34 being shown by way of example in FIG. 3A, the light-emitting diodes LED being arranged in sets of light-emitting diodes LED.

FIG. 3B is a schematic partial cross-sectional view of the structure obtained after the following steps:
forming an insulating layer 74 extending over the lateral flanks of a lower portion of each light-emitting diode LED, and extending over the insulating layer 70 between the light-emitting diodes LED;
forming an electrode layer 76 covering each light-emitting diode LED and further extending over the insulating layer 74 between the light-emitting diodes LED;
forming a protective dielectric layer 78 extending over the layer 76; and
forming a planarizing layer 80 extending over layer 78 and having a planar free face 81.

FIG. 3C is a schematic partial cross-sectional view of the structure obtained after the following steps:
attaching a handle 82 to the face 81; and
removing the substrate 60 and the germination layer 66 by any known means.

FIG. 3D is a schematic partial cross-sectional view of the structure obtained after forming, on the insulating layer 68, an interconnection structure 83 comprising a stack 84 of insulating layers and conductive tracks 86 of different metallization levels, the conductive tracks 86 of two metallization levels being shown by way of example in FIG. 3D, and conductive vias 88 extending through the stack 84 of insulating layers, the insulating layer 68, and the insulating layer 74, and connecting the electrode layer 76 to the conductive tracks 86, the interconnection structure 83 having a preferably flat free face 90.

FIG. 3E is a schematic partial cross-section of the structure obtained after a step of attaching the substrate 32 to the face 90, for example by molecular bonding.

FIG. 3F is a schematic partial cross-sectional view of the structure obtained by the following steps:
removal of handle 82 by any known means;
etching away the insulating layer 80 at certain sets of light-emitting diodes LED to expose these sets of light-emitting diodes, and between the sets of light-emitting diodes LED, the insulating layer 80 being kept for the other sets of light-emitting diodes LED;
forming photoluminescent blocks 94, 96 covering the sets of exposed light-emitting diodes LED, two photoluminescent blocks 94, 96 being shown by way of example in FIG. 3F;
forming reflective walls 98 between blocks 94, 96;—forming an encapsulation layer 100 covering each block 94, 96, and the protective dielectric layer 78 between the blocks 94, 96, the encapsulation layer 100 comprising the non-etched portions of the insulating layer 80; and
forming, in the encapsulation layer 100, at least one color filter 102, for example a single yellow filter, covering at least some of the photoluminescent blocks 94, 96, a single filter 102 covering both photoluminescent blocks 94, 96 being shown by way of example in FIG. 3F.

The structure resting on the substrate 32 forms the previously described plate 30, and the free face 36 of the encapsulation layer 100 corresponds to the previously described face 36.

FIG. 3G is a schematic partial cross-sectional view illustrating the step previously described in relation to FIG. 1C, comprising attaching the face 36 to support 5 by a layer of adhesive 50. In FIG. 3G, the support 5 is shown here with two weakened areas 24, and comprising an opaque layer 104 on the side opposite the plate 30. The opaque layer 104 may not be present. The opaque layer 104 makes the support 5 non-transparent, which can facilitate detecting and handling the structure by machines.

FIG. 3H is a schematic partial cross-sectional view illustrating the step described above in relation to FIG. 1D, comprising removing the substrate 32.

FIG. 3I is a schematic partial cross-sectional view of the structure obtained after a step of forming openings 106 in the stack 84 of insulating layers to expose conductive tracks 86.

FIG. 3J is a schematic partial cross-sectional view of the structure obtained after a step of removing the opaque layer 104. Alternatively, the opaque layer 104 can be removed at a later step of the manufacturing method, in particular after the steps described below in relation to FIG. 3L.

FIG. 3K is a schematic partial cross-sectional view of the structure obtained after a step of forming conductive pads 108 in contact with conductive tracks 86 exposed through openings 106, a single conductive pad 108 being shown as an example in FIG. 3K. Each conductive pad 108 may have a single-layer or multi-layer structure.

FIG. 3L is a schematic partial cross-sectional view illustrating the step described above in relation to FIG. 1E, comprising etching trenches 52 in the plate 30 at desired separation lines of the electronic devices 34.

FIG. 3M is a schematic partial cross-sectional view illustrating the step described above in relation to FIG. 1F, comprising thinning the support 5.

FIG. 3N is a schematic partial cross-sectional view illustrating the step described above in relation to FIG. 1G, comprising breaking the support 5 at the weakened areas 24 to separate the optoelectronic devices 34.

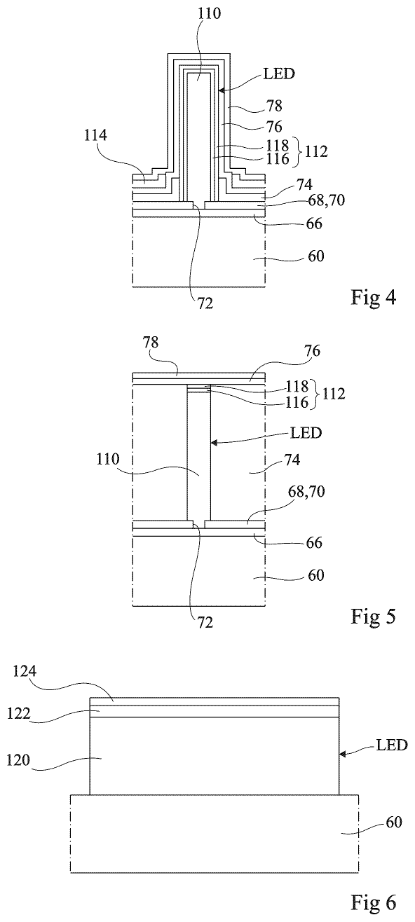

FIG. 4 shows an embodiment of the light-emitting diodes LED. According to one embodiment, each light-emitting diode LED comprises a wire 110 in contact with the germination layer 66 through one of the openings 72, and a shell 112 comprising a stack of semiconductor layers covering the side walls and top of the wire 110. Such a configuration is referred to as radial. The assembly formed by each wire 110 and the associated shell 112 constitutes the light-emitting diode LED. FIG. 4 also shows a reflective layer 114, for example metallic, covering the electrode layer 76 between the wires 110 and in direct physical contact with the electrode layer 76.

The shell 112 may comprise a stack of several layers, particularly including an active layer 116 and a bonding layer 118. The active layer 116 is the layer from which the majority, preferably all, of the radiation provided by the light-emitting diode LED is emitted. According to one example, the active layer 116 may comprise confinement means, such as a single quantum well or multiple quantum wells. The bonding layer 118 may comprise a stack of semiconductor layers of the same III-V material as the wire 110, but of the opposite conductivity type as respect to the wire 110.

FIG. 5 shows an example of a light-emitting diode LED. The light-emitting diode LED shown in FIG. 5 comprises all the elements of the light-emitting diode LED shown in FIG. 4, with the difference that the shell 112 is present only at the top of the wire 110. Such a configuration is referred to as axial.

Forming the light-emitting diodes LED, i.e. causing the growth of the wires 110 in the openings 72, and forming the shells 112 covering the wires 110 can be performed, for example, by Metal-Organic Chemical Vapor Deposition (MOCVD) or any other suitable method.

FIG. 6 shows an embodiment of the light-emitting diodes LED. The light-emitting diode LED shown in FIG. 6 has a two-dimensional structure in that it is manufactured by forming a stack of substantially flat semiconductor layers on the substrate 60, and then delimiting the light-emitting diode, for example by etching trenches in the stack of semiconductor layers. The light-emitting diode shown in FIG. 6 comprises a semiconductor layer 120 doped with a first type of conductivity, covered by an active layer 122, itself covered by a semiconductor layer 124 doped with a second type of conductivity.

The substrate 60 may be a single-piece structure or a layer covering a support made of another material. The substrate 60 is preferably a semiconductor substrate, e.g. a silicon, germanium, silicon carbide, III-V compound, such as GaN or GaAs, substrate or a ZnO substrate. Preferably, the substrate 60 is a single-crystal silicon substrate. The substrate 60 may be a multilayer structure of the silicon-on-insulator type, also known as SOI.

The germination layer 66 is made of a material that promotes wire growth. By way of example, the material constituting the germination layer 66 may be a nitride, carbide, or boride of a transition metal from column IV, V, or VI of the Periodic Table of the Elements, or a combination of these compounds.

According to another embodiment, the germination layer 66 may not be present. According to another embodiment, the germination layer 66 may be replaced by germination studs, for example formed at the bottom of the openings 72.

Each insulating layer 68, 70, 74, 78, 80, and the encapsulation layer 100 can be made of a dielectric material, for example silicon oxide (SiO₂), silicon nitride (SiₓN_{y}, where x is about 3 and y is about 4, for example Si₃N₄), silicon oxynitride (in particular of the general formula SiOₓN_{y}, for example Si₂ON₂), aluminum oxide (Al₂O₃), hafnium oxide (HfO₂), titanium dioxide (TiO₂), or diamond. Each insulating layer 68, 70, 74, 78, 80 can be a single-layer structure, or a stack of two or more layers.

The electrode layer 76 is adapted to allow the electromagnetic radiation emitted by the light-emitting diodes to pass through. The material forming the electrode layer 76 can be a transparent, conductive material such as indium-tin oxide (ITO), aluminum-or gallium-doped zinc oxide, or graphene. The thickness of the electrode layer 76 can be between 0.01 μm and 10 μm.

According to one embodiment, each photoluminescent block 94, 96 is located opposite one of the light-emitting diodes LED or a set of light-emitting diodes LED. Each photoluminescent block 94, 96 comprises phosphors adapted, when excited by the light emitted by the associated light-emitting diode LED, to emit light at a wavelength different from the wavelength of the light emitted by the associated light-emitting diode LED.

Various embodiments and variants have been described. Those skilled in the art will understand that certain features of these embodiments can be combined and other variants will readily occur to those skilled in the art. In particular, . . .

[symbol]

Finally, the practical implementation of the embodiments and variants described herein is within the capabilities of those skilled in the art based on the functional description provided hereinabove.

1. A method for manufacturing an electronic device, comprising:
manufacturing a plate comprising several copies of the electronic device, the plate being attached to a substrate;
forming weakened areas in a support by means of a laser;
attaching the plate to the support after forming the weakened areas;
removing the substrate after attaching the plate to the support;
etching the plate in the extension of the weakened areas after removal of the substrate; and
breaking the support at the weakened areas to separate the electronic devices.

2. The method according to claim 1, wherein attaching the plate to the support is performed by bonding.

3. The method according to claim 2, wherein attaching the plate to the support is performed by bonding with a layer of adhesive.

4. The method according to claim 2, wherein attaching the plate to the support is performed by molecular bonding.

5. The method according to claim 1, comprising, after attaching the plate to the support, and before breaking the support at weakened areas, a step of thinning the support.

6. The method according to claim 1, wherein etching the plate in the extension of the weakened areas is performed by dry etching or wet etching.

7. The method according to claim 1, wherein the step of attaching the plate to the support after forming the weakened areas comprises a step of positioning first marks of the support relative to second marks of the plate, so that each electronic device to be separated is positioned between two weakened areas of the weakened areas.

8. The method according to claim 1, wherein the support is laser-transparent at least in weakened areas.

9. The method according to claim 1, wherein the support is at least partly made of glass, quartz, or sapphire.

10. The method according to claim 1, wherein the electronic device comprises light-emitting diodes (LED).
The method according to claim 10, wherein each light-emitting diode comprises a three-dimensional semiconductor element of nanometric or micrometric size, corresponding to a microwire, nanowire or pyramid-shaped structure of nanometric or micrometric size, and an active layer covering the three-dimensional semiconductor element.
